(19) United States
(12) Patent Application Publication
(10) Pub. No.: US 2023/0369356 A1
(43) Pub. Date: Nov. 16, 2023

(54) LIGHT SENSING PANEL, LIGHT SENSING DISPLAY PANEL, AND METHOD FOR OPERATING LIGHT SENSING PANEL

(71) Applicant: HANNSTOUCH SOLUTION INCORPORATED, Tainan City (TW)

(72) Inventor: Che-Yu CHUANG, Tainan City (TW)

(21) Appl. No.: 17/663,666

(22) Filed: May 16, 2022

(51) Int. Cl. H01L 27/146

(52) U.S. Cl. CPC H01L 27/14603; H04N 5/378

(57) ABSTRACT

A light sensing panel includes a substrate, at least one readout line, at least one scan line, and at least one pixel unit. The substrate has an array region and a peripheral region. The readout line and the scan line extend at least over the array region of the substrate. The pixel unit is over the array region of the substrate and electrically connected to the readout line and the scan line. The pixel unit at least includes a sensing switch device, a light sensing device, and a reference light sensing device. A first terminal of the sensing switch device is connected to the readout line. The light sensing device is connected between a second terminal of the sensing switch device and a voltage source. The reference light sensing device is connected between the second terminal of the sensing switch device and a grounded source.

### BACKGROUND

### Field of Invention

The present disclosure relates to a light sensing panel, a light sensing display panel, and a method for operating the light sensing panel.

### Description of Related Art

Photoelectric sensors can convert light into current or voltage signals. The photoelectric sensors can be manufactured in the form of thin film transistors and arranged in an array, which is then used in the fields of optical touch, fingerprint recognition, X-ray detection, etc. The photoelectric sensor may include a semiconductor thin film having a suitable band gap corresponding to the wavelength of light to be absorbed.

### SUMMARY

In some embodiments of the present disclosure, a switching and grounding path is added to the electrical circuit for releasing parasitic capacitance charge, thereby preventing the parasitic capacitance charge from affecting a result of the integrator.

According to some embodiments of the present disclosure, a light sensing panel includes a substrate, at least one readout line, at least one scan line, at least one pixel unit, a readout circuit, and at least one switch device. The substrate has an array region and a peripheral region at at least one side of the array region. The at least one readout line extends over the array region of the substrate. The at least one scan line extends over the array region of the substrate. The at least one pixel unit is over the array region of the substrate and electrically connected to the readout line and the scan line. The pixel unit at least comprises at least one light sensing device. The readout circuit comprising at least one integrator. The integrator has an input terminal connected to a portion of the readout line. The at least one switch device is over the peripheral region of the substrate. The switch device has a first terminal connected to the portion of the readout line and a second terminal grounded.

In some embodiments, the portion of the readout line extends to the peripheral region of the substrate.

In some embodiments, the light sensing panel further comprises a charge-releasing signal line connected to a control terminal of the at least one switch device.

In some embodiments, the scan line extends along a direction, and the charge-releasing signal line extends along the direction.

In some embodiments, a plurality of the switch devices are respectively connected to a plurality of the readout lines, the light sensing panel further comprises a charge-releasing signal line connected to a plurality of control terminals of the switch devices.

In some embodiments, the light sensing device comprises a semiconductor layer, a first source/drain electrode, a second source/drain electrode, and a gate electrode, wherein the first source/drain electrode and the second source/drain electrode are respectively connected to two opposite terminals of the semiconductor layer, and the gate electrode overlaps a portion of the semiconductor layer adjoining the first source/drain electrode.

In some embodiments, the gate electrode is electrically connected to the first source/drain electrode.

In some embodiments, the pixel unit further comprises a sensing switch device, a control terminal of the sensing switch device is connected to the scan line, and two terminals of the sensing switch device are respectively connected to the readout line and the light sensing device.

In some embodiments, a material of a semiconductor layer of the switch device is the same as a material of a semiconductor layer of the light sensing device.

According to some embodiments of the present disclosure, a light sensing display panel includes the aforementioned light sensing panel and at least one data line. The data line is disposed over the substrate. The pixel unit further includes a display switch device and a pixel electrode, a control terminal of the display switch device is connected to the scan line, and two terminals of the display switch device are respectively electrically connected to the data line and the pixel electrode.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic top view of a light sensing panel according to some embodiments of the present disclosure.

FIG. 1B is a circuit diagram of a portion of the light sensing panel of FIG. 1A.

FIG. 2 is a signal diagram of operating a light sensing panel according to some embodiments of the present disclosure.

FIG. 3A is a schematic top view of a light sensing panel according to some embodiments of the present disclosure.

FIG. 3B is a schematic cross-sectional view taken along line 3B-3B in FIG. 3A.

FIG. 4 is a schematic partial cross-sectional view of a light sensing panel according to some embodiments of the present disclosure.

FIG. 5 is a schematic top view of a light sensing display panel according to some embodiments of the present disclosure.

FIG. 6 is a schematic partial cross-sectional view of a light sensing display panel according to some embodiments of the present disclosure.

### DETAILED DESCRIPTION

The following invention provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

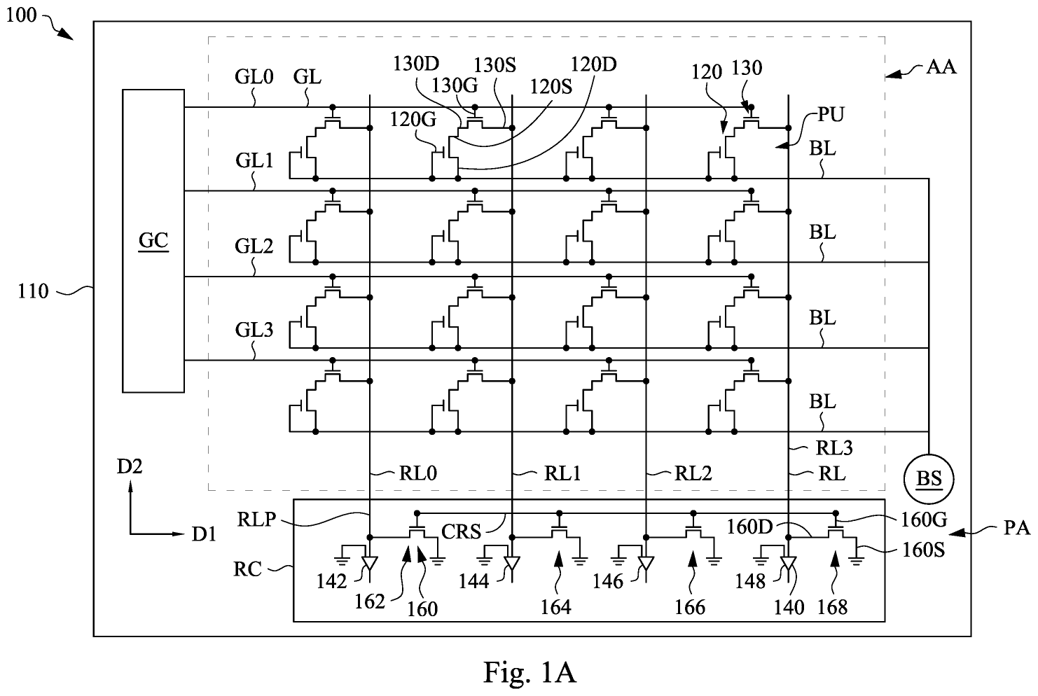

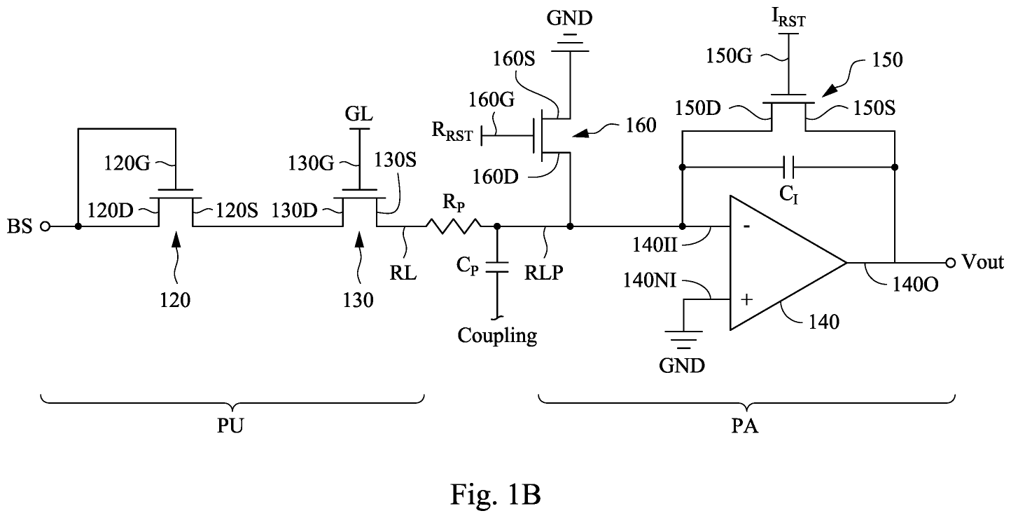

FIG. 1A is a schematic top view of a light sensing panel 100 according to some embodiments of the present disclosure. The light sensing panel 100 includes a substrate 110, plural pixel units PU, plural scan lines GL (e.g., scan lines GL0-GL3), readout lines RL (e.g., readout lines RL0-RL3), a bias line BL, scan driving circuit GC, and a readout circuit RC. The substrate 110 may include an array region AA and a peripheral region PA at at least one side of the array region AA, the pixel unit PU is disposed over the array region AA, the scan lines GL (e.g., scan lines GL0-GL3), the readout lines RL (e.g., readout lines RL0-RL3), and the bias line BL extend over the array region AA and to the peripheral region PA. The scan driving circuit GC and the readout circuit RC may be disposed over the peripheral region PA or connected to the peripheral region PA.

In the present embodiments, each of the pixel units PU is connected to a scan line GL (e.g., one of scan lines GL0-GL3) and a readout line RL (e.g., one of readout lines RL0-RL3). The scan lines GL (e.g., scan lines GL0-GL3) can be connected to the scan driving circuit GC, thereby time-sequentially providing scan signals to the pixel units PU. The readout lines RL can be connected to the readout circuit RC, thereby sending currents to the readout circuit RC. The bias line BL is connected to a voltage source BS, in which the voltage source BS provides a suitable and stable voltage potential. In some embodiments, the scan lines GL, the readout lines RL, and the bias line BL are electrically disconnected from each other. In some embodiments, the scan lines GL extend along a first direction D1, the readout lines RL extend along a second direction D2, and the first direction D1 intersects the second direction D2. For example, the first direction D1 is perpendicular to the second direction D2. In the present embodiments, the bias line BL extends along the first direction D1 and parallel with the scan lines GL. Of course, it should not limit the scope of the present disclosure. In some other embodiments, the bias line BL may extend along the second direction D2 and parallel with the readout lines RL.

In the present embodiments, each of the pixel units PU may include a light sensing device 120 and a sensing switch device 130. The light sensing device 120 may include a control terminal 120G, a first terminal 120D, and a second terminal 120S, in which a resistance between the first terminal 120D and the second terminal 120S may be controlled by light and a signal applied on the control terminal 120G. The sensing switch device 130 may include a control terminal 130G, a first terminal 130D, and a second terminal 130S, in which a resistance between the first terminal 130D and the second terminal 130S may be controlled by a signal applied on the control terminal 130G.

In some embodiments, the first terminal 120D and the control terminal 120G of the light sensing device 120 can be connected to the voltage source BS through the bias line BL, and the second terminal 120S of the light sensing device 120 can be connected to the readout line RL (e.g., the readout lines RL0-RL3) through the sensing switching device 130. Specifically, The control terminal 130G of the sensing switch device 130 is connected to the scan line GL (e.g., the scan lines GL0-GL3), the first terminal 130D of the sensing switch device 130 is connected to the second terminal 120S of the light sensing device 120, and the second terminal 130S is connected to the readout line RL (e.g., the readout lines RL0-RL3). Through the configuration, as the scan driving circuit GC sends signals to the respective scan lines GL0-GL3, the sensing switch devices 130 of the respective pixel units PU can be sequentially turned on. Thus, currents generated by the light sensing devices 120 may flow through the sensing switch devices 130, and then be sent to the readout circuit RC by the respective readout lines RL (e.g., the readout lines RL0-RL3).

In some embodiments, the readout circuit RC may include an integrator 140 (e.g., integrators 142-148), in which the integrator 140 has an inverting input terminal 140II, a non-inverting input terminal 140NI, and an output terminal 140O (referring to FIG. 1B). The readout line RL may have a portion RLP extending to the peripheral region PA. The inverting input terminal 140II of the integrator 140 (referring to FIG. 1B) may be connected to the portion RLP of the readout line RL, and the non-inverting input terminal 140NI may be grounded. Through the configuration, the integrator 140 can integrate aforementioned current (or charge) into voltage, by measuring the magnitude of the voltage, a light intensity can be calculated and obtained.

FIG. 1B is a circuit diagram of a portion of the light sensing panel of FIG. 1A. Reference is made to FIGS. 1A and 1B. An integrator reset switch device 150 and an integrator capacitor CI are disposed between the inverting input terminal 140II and the output terminal 140O of the integrator 140. The integrator reset switch device 150 may include a control terminal 150G, a first terminal 150D, and a second terminal 150S, in which a resistance between the first terminal 150D and the second terminal 150S may be controlled by a signal applied on the control terminal 150G. The output terminal 140O of integrator 140 can be considered as an output terminal 140O where the signal of the readout line RL have been integrated.

In some cases, the electric circuit of the readout line RL may include parasitic capacitance C_{P} and parasitic resistance RP, and therefore an actual voltage obtained from the integrated may be affected by the charges passing the light sensing device 120 and the charges of the parasitic capacitance C_{P}, which will cause inaccurate light intensity calculation.

In some embodiments of the present disclosure, the light sensing panel 100 may include a switch device 160 (e.g., switch devices 162-168) for releasing charges. Each of the switch device 160 may include a control terminal 160G, a first terminal 160D, and a second terminal 160S, in which a resistance between the first terminal 160D and the second terminal 160S may be controlled by a signal applied on the control terminal 160G. In the present embodiments, the control terminal 160G can be provided with a charge-releasing signal R_{RST}, for example, by a charge-releasing signal line CRS (referring to FIG. 1A). In the present embodiments, the first terminals 160D of the respective switch devices 160 are connected to a terminal of the readout line RL adjacent to the integrator 140 (e.g., the portion RLP of the readout line RL), the second terminals 160S of the respective switch devices 160 may be connected to a low voltage source (e.g., grounding voltage source GND). A voltage potential of the low voltage source (e.g., grounding voltage source GND) is lower than a voltage potential of the voltage source BS. Through the configuration, charge accumulated by the parasitic capacitance may be eliminated through the switch device 160, thereby lowering the effect of the capacitance to the integrator, which in turn may improve the accuracy in light intensity calculation.

In some embodiments, the charge-releasing signal line CRS may extend along a direction parallel with the extending direction D1 of the scan line GL. The charge-releasing signal line CRS may be connected to the control terminals 160G of the plural switch devices 162-168, and first terminals 160D of the switch devices 162-168 are respective connected to the portions RLP of the readout lines RL0-RL3.

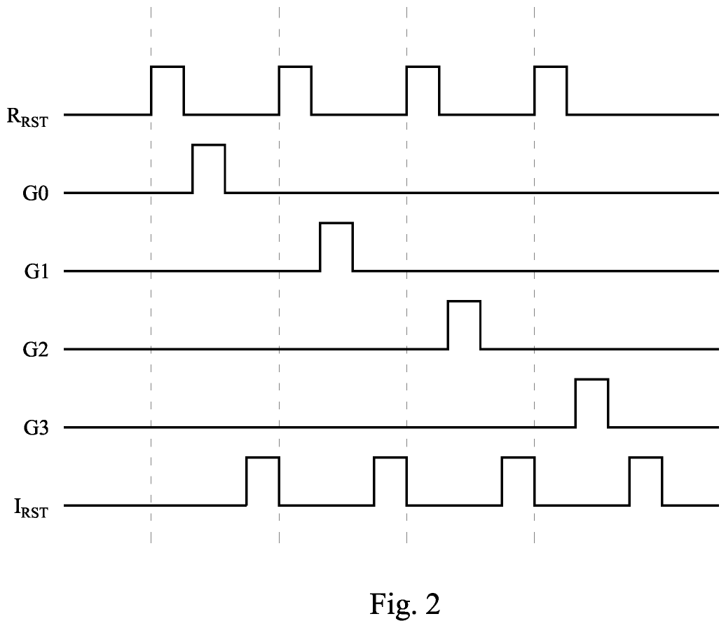

FIG. 2 is a signal diagram of operating a light sensing panel according to some embodiments of the present disclosure. Reference is made to FIGS. 1A, 1B, and FIG. 2. The scan driving circuit GC provides scan signals G0-G3 to the respective scan lines GL0-GL3, the charge-releasing signal R_{RST} can be provided from suitable electrical circuit (e.g., the readout circuit RC), through the charge-releasing signal line CRS, and to the switch device 160. The readout circuit RC may provide an integrator reset signal I_{RST} to the integrator reset switch device 150. Herein, before providing the scan signal (e.g., one of the scan signals G0-G3) to the pixel units PU, the charge-releasing signal R_{RST} may be provided to the switch device 160 for releasing charges; afterward, the scan signal (e.g., one of the scan signals G0-G3) is provided to the pixel unit PU for a sending sensing signal to the integrator 140; after the integration performed by the integrator 140, the integrator reset signal I_{RST} is provided, thereby resetting the integrator 140 through the integrator reset switch device 150. After these steps, another scan signals (e.g., another one of the scan signals G0-G3) is provided to another pixel unit PU. In the present embodiments, control terminals 160G of the switch devices 162-168 are connected to a same charge-releasing signal line CRS. Through the configuration, after turning on one of the scan signals G0-G3 and reading sensing signals of a row of the pixel units PU, all the readout line RL are performed with a charge-releasing step.

In some embodiments, the pulse design of the signal R_{RST} and the integrator reset signal I_{RST} makes the operation in a way that after turning on one of the scan signals G0-G3, the integrator 140 is reset first followed by the charge-releasing step. In some other embodiments, the pulse design can be changed in a way that after turning on one of the scan signals G0-G3, the charge-releasing step is performed first followed by resetting the integrator 140. In the present embodiments, the pulses of the signal R_{RST} may not overlap the pulses of the integrator reset signal I_{RST}, such that resetting the integrator 140 and the charge-releasing step are performed at different timings. Alternatively, in some other embodiments, the pulses of the signal R_{RST} may overlap or partially overlap the pulses of the integrator reset signal I_{RST}, such that resetting the integrator 140 and the charge-releasing step are performed at the same timing or partially at the same timing.

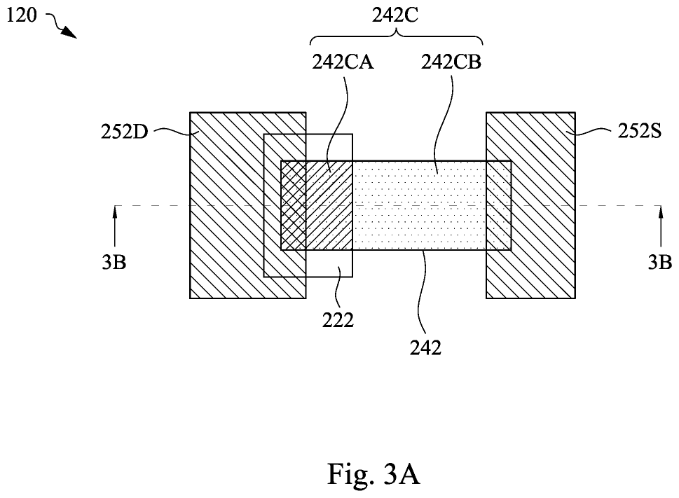

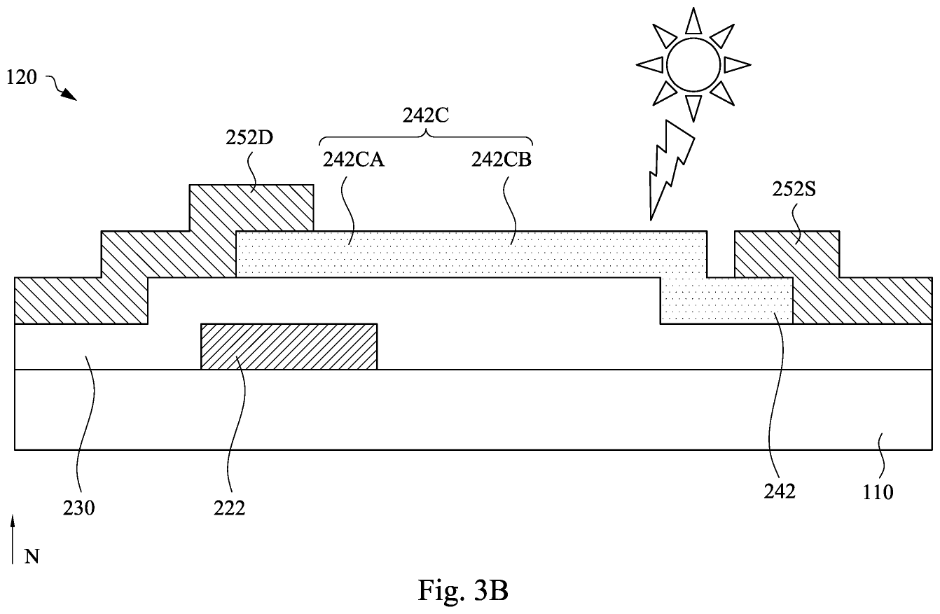

FIG. 3A is a schematic top view of a light sensing panel according to some embodiments of the present disclosure. FIG. 3B is a schematic cross-sectional view taken along line 3B-3B in FIG. 3A. The light sensing device 120 is disposed over a substrate 110. The light sensing device 120 includes a gate electrode 222, a insulating layer 230, a semiconductor layer 242, and source/drain electrodes 252S, 252D, in which the gate electrode 222 and the source/drain electrodes 252D, 252S respectively correspond to the control terminal 120G, the first terminal 120D, and the second terminal 120S in FIGS. 1A and 1B. The gate electrode 222 may be disposed over the substrate 110. The insulating layer 230 may be disposed over the gate electrode 222. The semiconductor layer 242 may be disposed over the insulating layer 230. The source/drain electrodes 252S and 252D are respective connected to two opposite terminals of the semiconductor layer 242.

In some embodiments, the semiconductor layer 242 has a channel region 242C between the source/drain electrodes 252S and 252D. The gate electrode 222 is offset disposed, and thus the channel region 242C is divided into a switch area 242CA and a sensing are 242CB, in which the switch area 242CA overlaps the gate electrode 222 along a direction N, and the light sensing area 242CB does not overlap the gate electrode 222 along the direction N. And, the switch area 242CA may adjoin the source/drain electrode 252D. The direction N may be substantially normal to a top surface of the substrate 110. Through the configuration, an electron channel of an entirety of the channel region 242C of the semiconductor layer 242 (i.e., the switch area 242CA and the light sensing area 242CB) is controlled by the light, and thus can sense light, in which the electron channel of the switch area 242CA of the semiconductor layer 242 can be further controlled by the gate electrode 222.

Through the configuration, during the operation of the light sensing device 120, by applying an appropriate voltage onto the gate electrode 222, the switch area 242CA and the light sensing area 242CB of the semiconductor layer 242 sense light and thus generate electrical current, and the electrical current is detected to calculate the light intensity. In an example, a positive voltage is applied onto the gate electrode 222 and thus turning on the switch area 242CA, and the semiconductor layer 242 senses light and thus generates electrical current; at this point, the magnitude of the electrical current is mainly controlled by the light sensing area 242CB. In another example, a negative voltage is applied onto the gate electrode 222 and thus inhibiting the switch area 242CA, and the semiconductor layer 242 senses light and thus generates electrical current; at this point, the magnitude of the electrical current is mainly controlled by the switch area 242CA and the light sensing area 242CB. In the example where the gate electrode 222 is applied with the negative voltage, a change of the current induced by the light intensity is more obvious, and therefore the light sensing device 120 has a higher light-intensity resolution. In the present embodiments, the light sensing device 120, having an advantage of high light-intensity resolution, and can be used in optical fingerprint recognition. By sensing light reflected by fingerprint, fingerprint recognition can be achieved with improved accuracy.

Herein, “inhibiting” the switch area 242CA is referred to as increasing a value of electrical resistance of the semiconductor layer 242 by controlling an external electric field (e.g., the electric field generated by voltages applied onto the gate electrode 222). On the other hand, “turning on” the switch area 242CA is referred to as decreasing the value of electrical resistance of the semiconductor layer 242 by controlling the external electric field (i.e., the electric field generated by voltages applied onto the gate electrode 222).

In some embodiments, the substrate 110 can be a rigid substrate having a suitable hardness or a flexible substrate. The substrate can be made of glass, quartz, organic material (e.g., polymeric material), other suitable material, or the combination thereof.

In some embodiments, the gate electrode 222 can be formed by a suitable conductive material, such as molybdenum, titanium, chromium, tantalum, tungsten, aluminum, copper, other metals, their alloys, or combinations thereof. For example, a metal layer can be deposited over the substrate 110, and then be patterned by an etching process to form the gate electrode 222. The insulating layer 230 may be deposited on the gate electrode 222, and the insulating layer 230 may be formed by depositing a suitable insulating material, such as silicon nitride, silicon oxide, silicon oxynitride, or a combination thereof.

In some embodiments, the semiconductor layer 242 can be selected from semiconductor materials with appropriate energy gaps, which can absorb light and change their resistance accordingly. For example, the semiconductor layer 242 may be formed of a suitable semiconductor material, such as amorphous silicon, other suitable materials, or combinations thereof.

In some embodiments, source/drain electrodes 252S and 252D can be formed by a suitable conductive material, such as molybdenum, titanium, chromium, tantalum, tungsten, aluminum, copper, other metals, their alloys, or combinations thereof. In some embodiments, the source/drain electrodes 252S and 252D are formed by a same conductive material. For example, a metal layer is deposited over the substrate 110, and the metal layer is then patterned by an etching process to form the source/drain electrodes 252S and 252D. In some embodiments, a contact feature C1 may be disposed in the insulating layer 230 to electrically connect the gate electrode 222 to the source/drain electrode 252D of the light sensing device 120. Through the configuration, the electrical circuit configuration in FIG. 1B can be achieved. In some embodiments, formation of the contact feature C1 includes etching a contact opening in the insulating layer 230 by etching method, filling the contact opening with a conductive material, and removing the conductive material outside the contact opening by planarization process. The exemplary conductive material of the contact feature C1 may be molybdenum, titanium, chromium, tantalum, tungsten, aluminum, copper, other metals, their alloys, or combinations thereof.

Referring back to FIG. 1A, in some embodiments of the present disclosure, the switch device 160 can be directly disposed over the peripheral region PA of the substrate 110, and the scan driving circuit CG and the readout circuit may be disposed over a flexible printed circuit board, which is connected to the peripheral region PA of the substrate 110. Alternatively, in some other embodiments, the switch device 160, the scan driving circuit GC, and the readout circuit RC may be disposed over the flexible circuit printed board. Alternatively, in some still other embodiments, the switch device 160, the scan driving circuit GC, and the readout circuit RC may be disposed directly over the substrate 110.

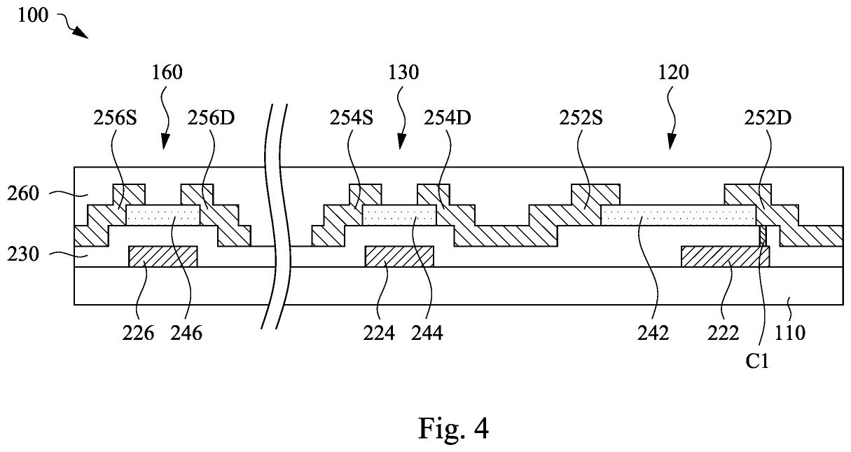

FIG. 4 is a schematic partial cross-sectional view of a light sensing panel according to some embodiments of the present disclosure. In some embodiments, at least two of the aforementioned light sensing device 120, sensing switch device 130, and switch device 160 can be thin film transistors formed by the same fabrication process, and the layers of these thin film transistors include substantially the same material and have substantially the same thickness.

For example, the sensing switch device 130 may include a gate electrode 224, a semiconductor layer 244, and source/drain electrodes 254S, 254D, in which the gate electrode 224 and the source/drain electrodes 254D, 254S respectively correspond to the control terminal 130G, the first terminal 130D, and the second terminal 130S in FIGS. 1A and 1B. The switch device 160 may include a gate electrode 226, a semiconductor layer 246, and source/drain electrodes 256S, 256D, in which the gate electrode 226 and the source/drain electrodes 256D, 256S respectively correspond to the control terminal 160G, the first terminal 160D, and the second terminal 160S in FIGS. 1A and 1B. At least two of the gate electrodes 222-226 can be formed by patterning a same conductive layer, such that at least two of the gate electrodes 222-226 include substantially the same material and have substantially the same thickness. At least two of the semiconductor layers 242-246 can be formed by patterning a same semiconductor layer, such that at least two of the semiconductor layers 242-246 include substantially the same material and have substantially the same thickness. At least two sets of the source/drain electrodes 252S and 252D, 254S and 254D, and 256S and 256D can be formed by patterning a same conductive layer, such that at least two sets of the source/drain electrodes 252S and 252D, 254S and 254D, and 256S and 256D include substantially the same material and have substantially the same thickness. Subsequently, an insulating layer 260 is formed over the light sensing device 120, the sensing switch device 130, and the switch device 160. The insulating layer 260 may include a suitable insulating material, such as silicon dioxide, silicon oxynitride, or a combination thereof.

In some embodiments of the present disclosure, the light sensing device 120, the sensing switch device 130, and the switch device 160 may adopt N-type channels or P-type channels, and not limited by those shown in figures. The semiconductor layers 242-246 may include amorphous silicon and n-type lightly doped (n+) amorphous silicon.

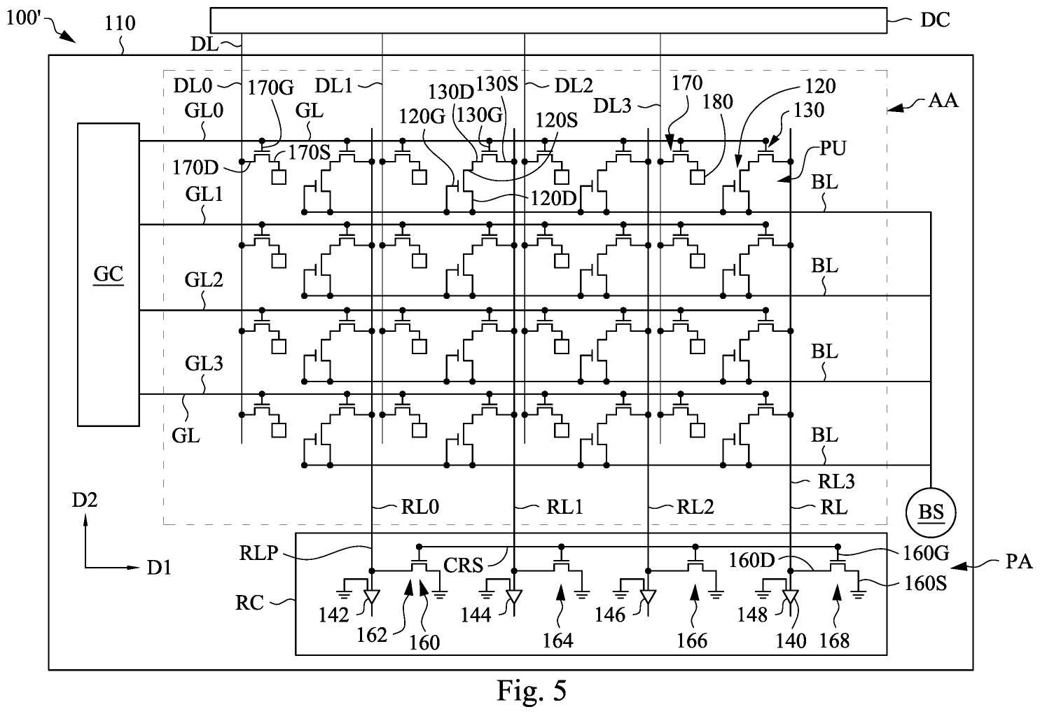

FIG. 5 is a schematic top view of a light sensing display panel 100′ according to some embodiments of the present disclosure. The light sensing display panel 100′ of the present embodiments is similar to the light sensing panel 100 in FIG. 1A, except that: the pixel unit PU may further include a display switch device 170 and a pixel electrode 180 in the present embodiments, so that the light sensing display panel 100′ can achieve the display effect.

The display switch device 170 may include a control terminal 170G, a first terminal 170D, and a second terminal 170S, in which the control terminal 170G is configured to control whether to establish an electrical conduction between the first terminal 170D and the second terminal 170S or not. The control terminal 170G can be connected to the scan line GL. The light sensing display panel 100′ may further include a data line DL, and the first terminal 170D and the second terminal 170S are respectively connected to the data line DL and the pixel electrode 180. The light sensing display panel 100′ further includes a data driving circuit DC to time-sequentially provide suitable data signals to respective data lines DL (e.g., the data lines DL0-DL3). In some embodiments, the data driving circuit DC may be directly disposed on the substrate. Alternatively, in some other embodiments, the data driving circuit DC can be disposed on a flexible circuit board, and the flexible circuit board is connected to the peripheral area PA of the substrate 110. Through the configuration, through the control of the data driving circuit DC and the scan lines GL, the data signals provided by the data driving circuit DC can be time-sequentially sent to the respective pixel electrodes 180 through the data lines DL, thereby controlling the light intensity of respective pixels and achieving display purpose.

In some embodiments, the light sensing display panel 100′ may be a liquid crystal display panel (LCD), and the pixel electrodes 180 may be configured to modulate the liquid crystal layer. Alternatively, in some embodiments, the light sensing display panel 100′ may be an organic light-emitting diode (e.g., active-matrix organic light-emitting diode (AMOLED)) panel or a light-emitting diode (LED) panel, The pixel electrode 180 can be used to control the organic light-emitting layer or the light-emitting diode.

In the present embodiments, as the display switch device 170 and the sensing switch device 130 of the same pixel unit PU are controlled by the same scan line GL, the display switch device 170 and the sensing switch device 130 in the same pixel unit PU can be turned on at the same time point. Through the configuration, in the pixel unit PU, at the same time point, an electrical conduction is built between the data line DL and the pixel electrode 180 through the display switch device 170 to achieve the display effect, and an electrical conduction is built between the light sensing device 120 and the readout line RL through the sensing switch device 130 to achieve the purpose of sensing light. By arranging the light sensing device 120 and the pixel electrode 180 in the same pixel unit PU, the resolution of the light sensing device 120 is comparable to the resolution of the pixel electrode 180 for display, thereby improving the sensing resolution. Other details of the present embodiments are similar to those described above, and not repeated herein.

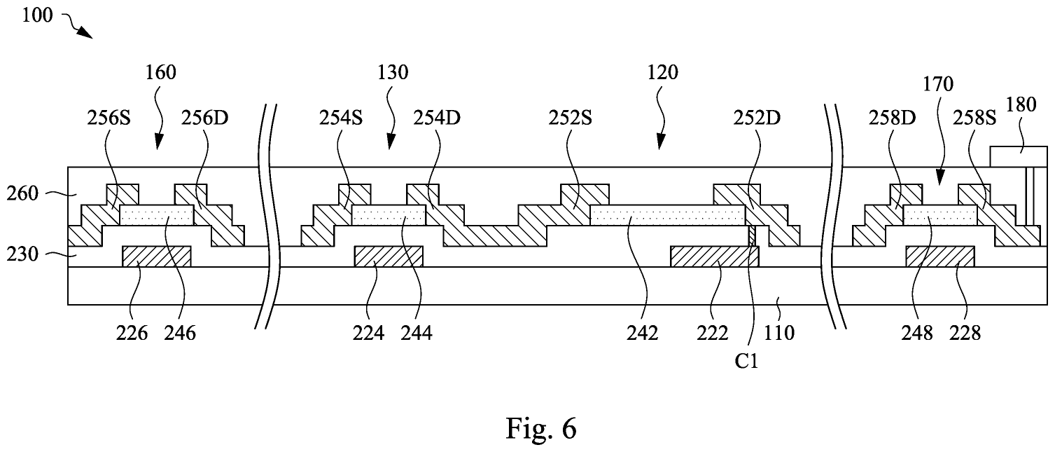

FIG. 6 is a schematic partial cross-sectional view of a light sensing display panel 100′ according to some embodiments of the present disclosure. In some embodiments, the aforementioned light sensing device 120, the sensing switch device 130, the display switch device 170, and the switch device 160 may be thin film transistors formed by the same fabrication process, and their layers have substantially the same material and thickness.

For example, the display switch device 170 may include a gate electrode 228, a semiconductor layer 248, and source/drain electrodes 258D and 258S, in which the gate electrode 228 and the source/drain electrodes 258D and 258S respectively correspond to a control terminal 170G, a first terminal 170D and a second terminal 170S in FIG. 5. At least two of the gate electrodes 222-228 may be formed by patterning the same conductive layer, such that at least two of the gate electrodes 222-228 may include the same material and have substantially the same thickness. At least two of the semiconductor layers 242-248 may be formed by patterning the same semiconductor thin film, such that at least two of the semiconductor layers 242-248 may include the same material and have substantially the same thickness. At least two sets of the source/drain electrodes 252S and 252D, 254S and 254D, 256S and 256D, and 258S and 258D may be formed by patterning the same conductive layer, such that at least two sets of the source/drain electrodes 252S and 252D, 254S and 254D, 256S and 256D, and 258S and 258D may include the same material and have substantially the same thickness. In the present embodiments, a suitable conductive material, such as a transparent conductive material (e. g., indium tin oxide), can be deposited on the insulating layer 260 and subjected to a patterning process to form the pixel electrode 180. Other details of the present embodiments are similar to those described above, and not repeated herein.

In some embodiments of the present disclosure, a switching and grounding path is added to the electrical circuit for releasing parasitic capacitance charge, thereby preventing the parasitic capacitance charge from affecting a result of the integrator.

The foregoing outlines features of several embodiments so that those skilled in the art may better understand the aspects of the present disclosure. Those skilled in the art should appreciate that they may readily use the present disclosure as a basis for designing or modifying other processes and structures. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A light sensing panel, comprising:
a substrate having an array region and a peripheral region at at least one side of the array region;
at least one readout line extending over the array region of the substrate;
at least one scan line extending over the array region of the substrate; and
at least one pixel unit over the array region of the substrate and electrically connected to the readout line and the scan line, wherein the pixel unit at least comprises at least one light sensing device;
a readout circuit comprising at least one integrator, wherein the integrator has an input terminal connected to a portion of the readout line; and
at least one switch device over the peripheral region of the substrate, wherein the switch device has a first terminal connected to the portion of the readout line and a second terminal grounded.

2. The light sensing panel of claim 1, wherein the portion of the readout line extends to the peripheral region of the substrate.

3. The light sensing panel of claim 1, further comprising:
a charge-releasing signal line connected to a control terminal of the at least one switch device.

4. The light sensing panel of claim 3, wherein the scan line extends along a direction, and the charge-releasing signal line extends along the direction.

5. The light sensing panel of claim 1, wherein a plurality of the switch devices are respectively connected to a plurality of the readout lines, the light sensing panel further comprises a charge-releasing signal line connected to a plurality of control terminals of the switch devices.

6. The light sensing panel of claim 1, wherein the light sensing device comprises a semiconductor layer, a first source/drain electrode, a second source/drain electrode, and a gate electrode, wherein the first source/drain electrode and the second source/drain electrode are respectively connected to two opposite terminals of the semiconductor layer, and the gate electrode overlaps a first portion of the semiconductor layer adjoining the first source/drain electrode.

7. The light sensing panel of claim 6, wherein a second portion of the semiconductor layer adjoining the second source/drain electrode is free of overlapping the gate electrode.

8. The light sensing panel of claim 6, wherein the gate electrode is electrically connected to the first source/drain electrode.

9. The light sensing panel of claim 1, wherein the pixel unit further comprises a sensing switch device, a control terminal of the sensing switch device is connected to the scan line, and two terminals of the sensing switch device are respectively connected to the readout line and the light sensing device.

10. The light sensing panel of claim 9, wherein a material of a semiconductor layer of the sensing switch device is the same as a material of a semiconductor layer of the light sensing device.

11. The light sensing panel of claim 1, wherein a material of a semiconductor layer of the switch device is the same as a material of a semiconductor layer of the light sensing device.

12. A light sensing display panel, comprising:
the light sensing panel of claim 1; and
at least one data line disposed over the substrate, wherein the pixel unit further comprises a display switch device and a pixel electrode, a control terminal of the display switch device is connected to the scan line, and two terminals of the display switch device are respectively electrically connected to the data line and the pixel electrode.

13. A method for operating a light sensing panel, comprising:
providing a first scan signal to a first row of a plurality of pixel units, wherein the first row of the pixel units are respectively connected to a plurality of readout lines;
grounding the readout lines after the first scan signal is provided to the first row of pixel units; and
providing a second scan signal to a second row of the pixel units, wherein the second row of the pixel units are respectively connected to the readout lines.

14. The method of claim 13, wherein providing the second scan signal to the second row of the pixel units is performed when the readout lines are free of being grounded.

15. The method of claim 13, wherein grounding the readout lines comprises:
providing a charge-releasing signal to a plurality of charge-releasing switch devices, wherein each of the charge-releasing switch devices has a first terminal connected to one of the readout lines and a second terminal connected to a grounding voltage source.
